(19) United States
(12) Patent Application Publication
(10) Pub. No.: US 2007/0257661 A1
(43) Pub. Date: Nov. 8, 2007

(54) Current probing system

(76) Inventors: Michael J. Mende, Portland, OR (US); Robert A. Nordstrom, Beaverton, OR (US); Thomas J. Sharp, Tigard, OR (US)

Correspondence Address: WILLIAM K. BUCHER;TEKTRONIX, INC., 14150 S.W. KARL BRAUN DRIVE, P.O. BOX 500, MS 50-LAW, BEAVERTON, OR, 97077, US

(21) Appl. No.: 11/430,386

(22) Filed: May 8, 2006

(51) Int. Cl. G01R 15/20; G01R 15/18

(52) U.S. Cl. 324/117 R

(57) ABSTRACT

A current probing system for acquiring a current signal from a current carrying conductor has a current diverting element mounted on the conductor for serially coupling the current signal to a current probe. The current probe has a probe body and first and second electrically conductive contacts extending from one end of the probe body for connecting to the current diverting element. A current sensing circuit is coupled to the first and second electrically conductive contacts for generating an output signal representative of the current flowing in the current carrying conductor. An electrically conductive cable is coupled to receive the output signal from the current sensing device and extends from the other end of the probe body for coupling to an oscilloscope.

### BACKGROUND OF THE INVENTION

The present invention relates generally to current probes and more particularly to a current probing system for use with an oscilloscope that acquires a current signal from a current carrying conductor.

Current probes used with oscilloscopes apply transformer technology to measure current flowing in a conductor. The transformer has a ring-shaped magnetic core defining an aperture and may be a solid or closed core where a current carrying conductor is passed through the aperture of the ring-shaped magnetic core. Alternately, the transformer may have an open or split core where one side of the magnetic core is movable relative to the other sides. This allows the current carrying conductor to be passed through the aperture of the transformer without having to disconnect the current carrying conductor from a circuit. The current carrying conductor is passed through the aperture in the magnetic core and acts as the primary winding of the transformer. A secondary winding is wrapped around one side of the magnetic core. The current flowing in the current carrying conductor induces a magnetic flux that is linked to the magnetic core and the secondary winding. The magnetic flux causes a current to be generated in the secondary winding that produces a magnetic flux that is opposite to that generated by the current flowing in the current carrying conductor. In a passive current probe, the alternating current generated by the secondary winding is dropped across a transformer termination resistor which generates an AC voltage output. The voltage output is coupled via an electrical cable to an input channel of the oscilloscope. The oscilloscope processes the voltage signal for displaying a representation of the current signal.

Since transformers are AC signal coupling devices, passband of the transformer cut-off frequency is above the DC level. To allow the current probe to sense DC and low frequency current signals, an active current probe includes a Hall effect device in the magnetic core of the transformer. The Hall effect device is a semiconductor positioned in the magnetic core such that the magnetic flux in the magnetic core is substantially perpendicular to the Hall effect device. A bias is applied to the Hall device and the resulting voltage generated by the Hall effect due to the flux in the magnetic core is coupled to the input of a differential amplifier. The single ended output of the amplifier may be coupled to a power amplifier which generates a current output proportional to the voltage generated by the Hall effect device. The output of the Hall device amplifier or alternately the power amplifier is coupled to the secondary winding of the transformer such that the output current from the amplifier flowing through the secondary winding produces a flux that opposes the input magnetic flux over the frequency passband of the Hall effect device. In one implementation, the output of the Hall effect power amplifier is coupled to one side of the secondary winding with the other side of the winding coupled to the transformer termination resistor and amplifier circuitry. In another implementation, the output of the Hall effect amplifier is coupled via a resistor to the same side of the secondary as the amplifier circuitry. A capacitor is coupled to the input of a wideband amplifier in the amplifier circuitry for blocking the current from the Hall effect amplifier. The output of the Hall effect amplifier and the output of the wideband amplifier are summed at the input of a operational amplifier having a feedback resistor that provides a voltage output proportional to the combined current in the secondary winding of the transformer. The voltage output of the operational amplifier is a measure of the AC and DC components of the magnetic core flux. The output of the operational amplifier is coupled via an electrical cable to an input channel of the oscilloscope. Generally, active current probes are of the split-ring transformer type. U.S. Pat. Nos. 3,525,041, 5,477,135 and 5,493,211 describe the above current sensing circuits.

To measure the current passing through a conductor, the current probe must be coupled in series with the conductor. This proves difficult when the current carrying conductor is fixed to a substrate, such as a circuit trace on a circuit board. The general procedure for measuring the current in a current trace is to break the trace and solder a length of wire across the trace break. The wire is passed through the aperture in the transformer of the current probe where the wire acts as the primary winding of the transformer. Another procedure is to manufacture the circuit board with gaps in the traces and install square pins on either side of the gaps. A conductive jumper is coupled to the square pins during normal testing of the circuit board. When a current measurement is required the jumper is removed and a length of wire is connected between the square pins. As before, the wire is used as the primary winding of the transformer in the current probe.

Transformer based current probes have a number of limitations in measuring currents through circuit traces on a circuit board. Besides the requirement of breaking the circuit trace and installing a wire across the break, the sensitivity and accuracy of the resulting current measurement is limited by the repeatability of placing the wire in the same position within the magnetic core of the transformer and the repeatability of the split core being exactly aligned in the same position when it is opened and closed. What is needed is a current probing system that eliminates the need for breaking the current carry conductor and connecting a loop of wire across the break to allow the coupling of a current probe to measure the current following through the conductor. Further, the current probing system should provide greater repeatability in the sensitivity and accuracy of the current measurement.

### SUMMARY OF THE INVENTION

Accordingly, a current probing system for acquiring a current signal from a current carrying conductor that meets the above described needs has a current diverting element and a current probe. The current diverting element is mounted across a gap in the current carrying conductor and passes the current signal on the current carrying conductor in a first position. The current probe has a probe body and first and second electrically conductive contacts disposed in one end of the probe body. The first and second electrically conductive contacts are adapted for coupling to the current diverting element so that the current diverting element diverts the current signal from the current carrying conductor to the first and second electrically conductive contacts of the current probe in a second position. A current sensing circuit is disposed in the probe body and coupled to the first and second electrically conductive contacts for receiving the current signal. The current sensing circuit generates an output signal representative of the current flowing in the current carrying conductor. An electrically conductive cable is coupled to receive the output signal from the current sensing device for coupling the signal to an oscilloscope.

The current diverting device has electrically conductive contacts acting as switch elements with the switch elements electrically coupled together in the first position of the current diverting device and de-coupled in the second position of the current diverting device. The first and second electrically conductive probe contacts may be pins extending from the end of the probe body for engaging electrically conductive contacts acting as switch elements in the current diverting device. Downward pressure of the first and second electrically conductive probe contacts on the electrically conductive contacts of the current diverting device causes the contacts of the current diverting device to disengage in the second current diverting device position and couple the current signal to the current probe. The current probe may also include a non-conductive protrusion extending from the probe body adjacent to the first and second electrically conductive contacts. Downward pressure of the non-conductive protrusion extending from the probe body on at least one of the electrically conductive contact of the current diverting device causes the contacts of the current diverting device to disengage in the second current diverting device position and coupled to current signal to the current probe.

The current probing system may also include first and second electrically conductive leads. Each lead has one end coupled to one of the first and second electrically conductive contacts of the current probe and the other end coupled to a plug adapted for engaging electrically conductive contacts in the current diverting device acting as switch elements. Downward pressure of the plug on at least one of the electrically conductive contacts of the current diverting device causes the contacts of the current diverting device to disengage in the second current diverting device position and couple the current signal to the current probe.

The first and second electrically conductive contacts of the current probe may also be formed as a pin having insulating material disposed in the pin for electrically isolating the two contacts. The pin extends from the end of the probe body for engaging electrically conductive contacts in the current diverting device wherein downward pressure of the electrically conductive pin on the electrically conductive contacts of the current diverting device causes the electrically conductive contacts of the current diverting device to disengage in the second current diverting device position and couple the current signal to the current probe.

The current sensing circuit may be implemented as a magnetic sensor coupled to the first and second electrically conductive contacts of the current probe for sensing the magnetic flux of the current signal and generating a corresponding current output representative of the current signal. The output of the magnetic sensor is coupled to amplifier circuitry for generating the output signal representative of the current flowing in the current carrying conductor. The magnetic sensor may take the form of a transformer and Hall effect device or a flux gate. The transformer has a magnetic core with primary and secondary windings wrapped around the magnetic core. The primary winding is coupled to the first and second electrically conductive contacts for receiving the current signal from the current carry conductor and induces a magnetic flux within the magnetic core and the secondary winding for generating a current signal output in the secondary winding that is coupled to amplifier circuitry. The transformer may further include a magneto-electric converter disposed in the magnetic core that interacts with the magnetic flux within the magnetic core for generating a voltage signal representative of DC to low frequency current signals on the current carrying conductor with the voltage signal being coupled to the amplifier circuitry.

The objects, advantages and novel features of the present invention are apparent from the following detailed description when read in conjunction with appended claims and attached drawings.

### BRIEF DESCRIPTION OF THE DRAWINGS

FIG. 1 is a perspective view of the current probing system according to the present invention.

FIGS. 2A through 2C are cross-sectional view of various current diverting devices used in the current probing system according to the present invention.

FIG. 3 is a cross-sectional view of another current diverting device used in the current probing system according to the present invention.

FIG. 4 is a further example of the current probing system according to the present invention.

FIG. 5 is a schematic representation of a current sensing circuit in the current probing system according to the present invention.

FIG. 6 is a schematic representation of another current sensing circuit in the current probing system according to the present invention.

FIG. 7 is a schematic representation of a further current sensing circuit in the current probing system according to the present invention.

### DETAILED DESCRIPTION OF THE INVENTION

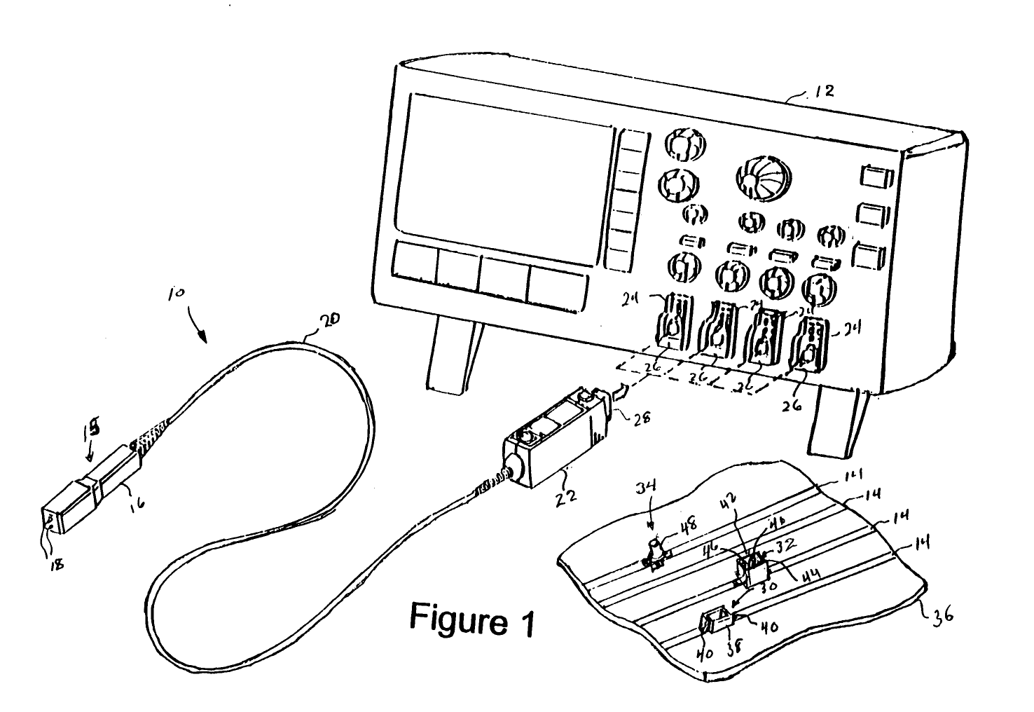

FIG. 1 is a perspective view of current probing system 10 for use with an oscilloscope 12 for acquiring a current signal from a current carrying conductor 14. The current probing system 10 has a current probe 15 having a probe body 16 in which is disposed a current sensing circuit. The current sensing circuit is electrically coupled to electrically conductive contacts 18 disposed in one end of the probe body 16. Extending from the other end of the probe body 16 is a conductive cable 20 for coupling an output signal from the current sensing circuit to the oscilloscope 12 and electrical power to the current sensing circuit. The conductive cable 20 is preferably coupled to a current probe control box 22 that is coupled to one of a number of input signal channel 24 of the oscilloscope 12. Each input signal channels 24 has a receptacle interface 26 with each interface having electrically conductive contacts and a coaxial signal jack. The current probe control box 22 has an plug interface 28 that mates with the receptacle interfaces 26 and has electrical contacts and a coaxial signal jack that interface with the corresponding electrical contacts and coaxial signal jack in receptacle interfaces 26. The interfaces 26 and 28 provide electrical power to the current probe 15 as well as providing communications between the current probe 15 and the oscilloscope 12. The interfaces 26 and 28 also provide a signal path between the current probe 15 and the oscilloscope 12.

The electrically conductive contacts 18 of the current probe 15 are adapted for electrically coupling to one of a number of current diverting devices 30, 32, 34 mounted on a current carrying conductor 14, such as a circuit trace formed on a circuit board 36 or the like. The current diverting devices 30, 32, 34 are positioned on the current carrying conductor 14 across a non-conductive gap in the current carrying conductor 14. The current diverting devices 30, 32, 34 couple the current signal across the non-conductive gap in a first position and couple the current signal to the current probe 15 in a second position. The current diverting device 30 has a housing 38 in which are disposed electrically conductive contact acting as switch elements. The electrically conductive contacts extend from the housing 38 forming electrically conductive leads 40 that are fixedly secured to the current carrying conductor 14 on either side of the non-conductive gap using solder, electrically conductive adhesive or the like. The current diverting device 32 has a housing 42 having a recess 44 in which is secured mating convex electrically conductive contacts 46 acting as switch elements. One end of each of the convex electrically conductive contacts extends from the housing and is fixedly secured to the current carrying conductor 14 on either side of the non-conductive gap using solder, electrically conductive adhesive or the like. A dual contact probing tip, to be described in greater detail below, is inserted between the convex contacts to coupled the current signal from the current carrying conductor to the current probe 15. The current diverting device 34 is a coaxial receptacle 48 mating with a coaxial plug to be described in greater detail below.

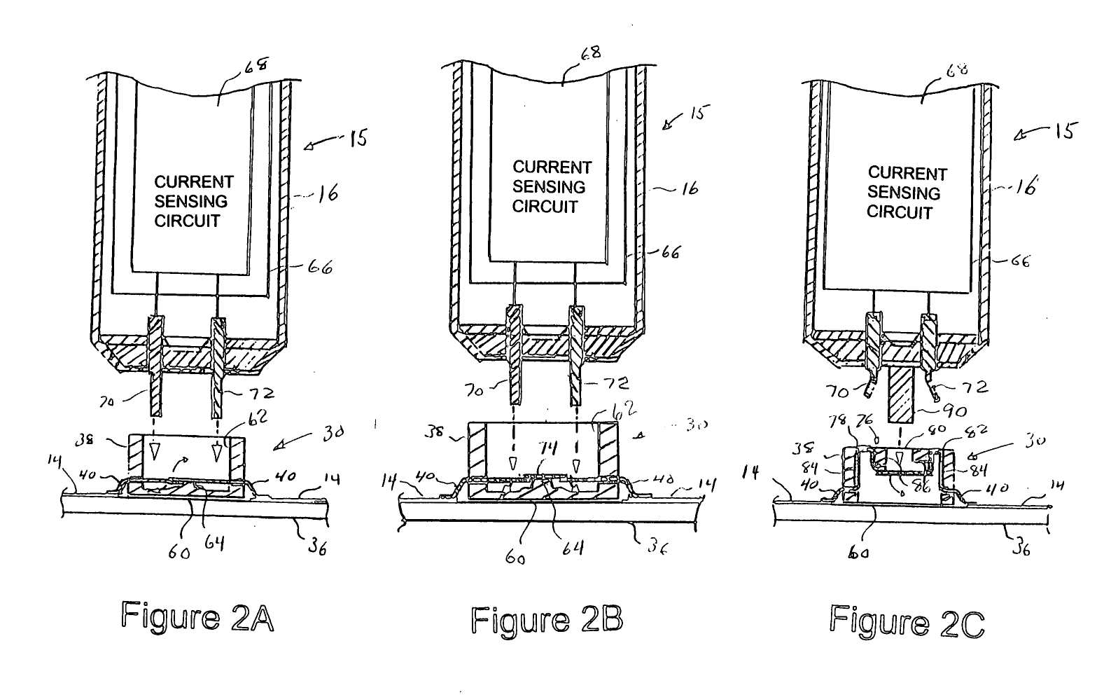

Referring to FIGS. 2A through 2C, there are shown cross-sectional views of examples of the current diverting device 30 and a portion of the current probe 15. The current diverting devices 30 in each of the drawing FIGS. 2A through 2C have a housing 38 and electrically conductive contacts 40 extending in opposite direction from the housing 38. The electrically conductive contacts 40 are coupled to the current carrying conductor 14 formed on the circuit board 36 on either side of the non-conductive gap 60. The housing 38 in FIG. 2A has a recess 62 in which is formed a raised pedestal 64 extending up from the bottom of the recess 62. The electrically conductive contacts 40 extend into the recess 62 of the housing 38 with one of the contacts 40 extending across and partially resting on the pedestal 64 and overlapping a portion of the other electrically conductive contact. The overlapped portions of the electrically conductive contacts 40 act as switch elements where electrically conductive contacts 40 couple the current signal across the non-conductive gap in the current carrying conductor 14 in the first current diverting device position.

The probe body 16 of the current probe 15 has a circuit board 66 on which is disposed a current sensing circuit 68. The current sensing circuit 68 is coupled to first and second electrically conductive contacts 70 and 72 that extend from the probe body 16. The current probe 15 is positioned over and lowered into the current diverting device 30. The downward pressure of the first and second electrically conductive contacts on the electrically conductive contacts 40 of the current diverting device 30 causes the electrically conductive contact 40 partially resting on the pedestal 64 to deflect upward and the other electrically conductive contact 40 to deflect downward. The resulting movement of the causes the electrically conductive contacts 40 to disengage. The current signal is diverted from the current carrying conductor 14 through the current sensing circuit 68 of the current probe 15 and back to the current carrying conductor 14 via the electrically conductive contacts 40 and the first and second electrically conductive contacts 70 and 72 of the current probe 15. The current diverting device 30 couples the current probe 15 in series with the current carrying conductor 14 and is the second position of the current diverting device 30. Removal of the current probe 15 from the housing recess 62 releases the downward pressure on the electrically conducive contacts 40 which causes the contacts to re-engage each other.

The current diverting device 30 in FIG. 2B is similar to the current diverting device 30 in FIG. 2A in that it has a housing 38 having a recess 62 in which is formed a raised pedestal 64 extending up from the bottom of the recess 62. The electrically conductive contacts 40 extend into the recess 62 of the housing 38. An electrically conductive element 74 is secured to the raised pedestal 64 with opposing ends of the electrically conducive element extending past the pedestal 64 and overlapping the electrically conducive contacts 40. The overlapped portions of the electrically conductive contacts 40 and the electrically conductive element 74 act as switch elements where electrically conductive contacts 40 and the electrically conductive element 74 couple the current signal across the non-conductive gap 60 in the current carrying conductor 14 in the first current diverting device position.

The current probe 15 is positioned over and lowered into the current diverting device 30. The downward pressure of the first and second electrically conductive contacts 70 and 72 on the electrically conductive contacts 40 of the current diverting device 30 causes the electrically conductive contacts 40 to deflect downward. The resulting movement of the electrically conducive contacts 40 causes the contacts 40 to disengage from the electrically conductive element 74. The current signal is diverted from the current carrying conductor 14 through the current sensing circuit 68 of the current probe 15 and back to the current carrying conductor 14 via the electrically conductive contacts 40 and the first and second electrically conductive contacts 70 and 72 of the current probe 15. As with the previously described current diverting device 30, the current probe 15 is coupled in series with the current carrying conductor 14 in the second position of the current diverting device 30. Removal of the current probe 15 from the housing recess 62 releases the downward pressure on the electrically conducive contacts 40 which causes the contacts 40 to re-engage with the electrically conductive element 74.

FIG. 2C illustrates another form of the current diverting device 30. The current diverting device 30 in FIG. 2C has a housing 38 having a top surface 76 in which three apertures 78, 80, 82 are formed. The electrically conductive contacts 40 extend into the housing 38 and are bent upward along the interior sidewalls 84. The electrically conductive elements 40 are bent horizontally at a substantially ninety degree angle to form electrical contact pads exposed in the respective apertures 78 and 82 in the top surface 76 of the housing 38. The electrically conductive contacts 40 are then bent downward at a substantially ninety degree angle along an intermediate interior wall 86 extending into the housing 38 defining the aperture 80. One side of the intermediate interior wall 86 extends farther into the housing 38 than the other side. One of the electrically conductive contacts 40 is bent horizontally at a substantially ninety degree angle along the underside of the longer side of the interior intermediate wall 86 defining a switch element. The other electrically conductive contact 40 is bent horizontally at a substantially ninety degree angle at a distance below the shorter side of the interior intermediate wall 86. The horizontal portion of the electrically conductive contact 40 that is below the shorter side of the interior intermediate wall 86 extends across the aperture 82 and overlaps the electrically conductive contact 40 along the underside of the longer side of the interior intermediate wall 86 defining a mating switch element. The overlapped portions of the electrically conductive contacts 40 couple the current signal across the non-conductive gap in the current carrying conductor 14 in the first current diverting device position.

The probe body 16 of the current probe 15 has a non-conductive protrusion 90 extending from the probe body 16 adjacent to the first and second electrically conductive contacts 70 and 72. The electrically conductive contacts 70 and 72 are angled slightly outward to mate with the electrically conductive contacts 40 in apertures 78 and 82 and allow flexing of the contacts 70 and 72 with downward movement of the current probe 15. The current probe 15 is positioned over and lowered into the current diverting device 30 with the non-conductive protrusion 90 aligned with the aperture 80. The downward movement of the current probe 15 causes the non-conductive protrusion 90 to contact the electrically conductive contact 40 extending across the aperture 80 and at the same time causing the electrically conductive contacts 70 and 72 to contact the electrically conductive contacts 40 in the aperture 78 and 82. Continued downward pressure on the current probe 15 causes the non-conductive protrusion 90 to deflect the electrically conductive contact 40 extending across the aperture 80 and disengage the electrically conductive contacts 40. The current signal is diverted from the current carrying conductor 14 through the current sensing circuit 68 in the current probe 15 and back to the current carrying conductor 14 via the electrically conductive contacts 40 and the first and second electrically conductive contacts 70 and 72 of the current probe 15. Removal of the current probe 15 from the housing 38 releases the downward pressure of the non-conductive protrusion 90 on the electrically conducive contact 40 extending across the aperture 118 which causes the contacts 102 to re-engage each other.

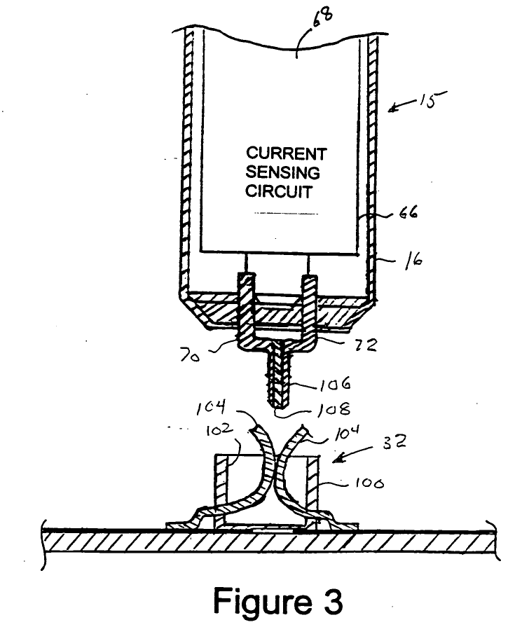

FIG. 3 is a perspective close-up view of the current diverting device 32. The current diverting device 32 has a housing 100 defining a recess 102 therein in which are disposed convex shaped electrically conductive contacts 104. The apex of the convex shaped contacts 104 are in mating electrical contact. The upper diverging portions of the convex contacts 104 form a V-shaped region for receiving the first and second electrically conductive contacts of the current probe 15. The lower diverging portions of the convex contacts 104 extend through the housing 100 and contact the current carrying conductor 14 on either side of the non-conductive gap 60. The mating portion of the convex electrically conductive contacts 104 act as switch elements where electrically conductive contacts 104 couple the current signal across the non-conductive gap 60 in the current carrying conductor 14 in the first current diverting device position.

For use with the type of current diverting device 32, the electrically conductive contacts 70 and 72 of the current probe 15 are modified to form a pin 106 having an insulating material 108 disposed between the first and second electrically conductive contacts 70 and 72 for electrically isolating contacts 70 and 72 from each other. The first and second electrically conductive contacts 70 and 72 extend from the probe body 16 and are angled toward each other and then downward to form the pin 106. The current probe 15 is positioned over and lowered into the current diverting device 32 so that the pin 106 is positioned in the V-shaped region of the convex shaped electrically conductive contacts 104. The downward movement of the pin 106 into the V-shaped region of the convex contacts 104 electrically couples the first and second electrically conductive contacts 70 and 72 of the pin 106 to the convex shaped electrically conductive contacts 104 and causes the mating apexes of the electrically conductive contacts 104 to disengage. The current signal is diverted from the current carrying conductor 14 through the current sensing circuit 68 of the current probe 15 and back to the current carrying conductor 14 via the electrically conductive contacts 104 and the first and second electrically conductive contacts 70 and 72 of the current probe 15. The current diverting device 32 couples the current probe 15 in series with the current carrying conductor 14 and is the second position of the current diverting device 32. Removal of the pin 106 from between the convex shaped electrically conductive contacts 104 causes the apexes of the convex shaped contacts 104 to re-engage.

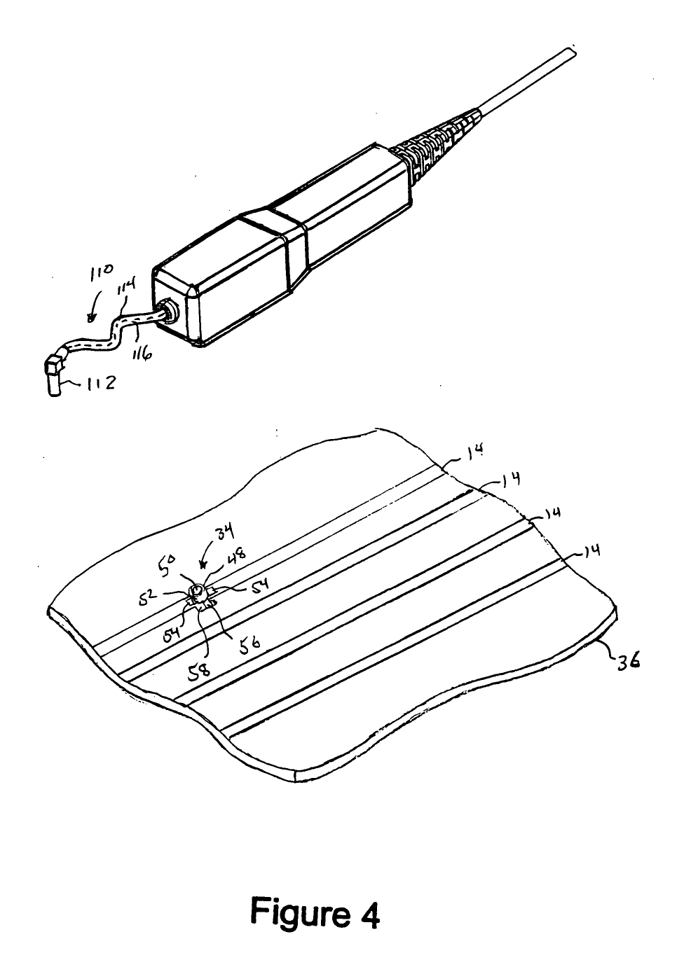

FIG. 4 is a perspective view of a further example of the current probing system 10. Extending from the probe body of the current probe 15 is a cable 110 having a coaxial connector 112 for mating with a coaxial receptacle 48 of the current diverting device 34. The first and second electrically conductive contacts 70 and 72 are first and second electrically conductive leads 114 and 116 disposed in the cable 110. One of the leads 114, 116 is electrically coupled to a center electrical conductor in the coaxial connector 112 and the other lead electrically is coupled to the electrically conductive outer body of the connector 112. The center electrical conductor and the electrically conductive outer body of the coaxial connector 112 are insulated from each other. The coaxial receptacle 48 of the current diverting device 34 has a central bore 50 insulated from an outer electrically conductive sleeve 52. Extend in opposite direction from the coaxial receptacle are electrically conductive contacts 54 that are fixedly secured to the current carrying conductor 14 on either side of the non-conductive gap 104 using solder, electrically conductive adhesive or the like. The electrically conductive contacts 54 extend into the coaxial receptacle 48 with one of the electrically conductive contacts extending across the central bore 50 to overlap the other electrically conductive contact 54 to act as switch elements. One of the electrically conductive contacts 54 is electrically coupled to the electrically conductive sleeve 52 via electrically conductive leads 56 extending from the coaxial receptacle 48 in a direction perpendicular to the other electrically conductive leads 54 and electrically coupled to the current carrying conductor 14 on the other side of the non-conductive gap 104 via contact pads 58 formed on the circuit board 36. The electrically conductive contacts 54 couple the current signal across the non-conductive gap 104 in the current carrying conductor 14 in the first current diverting device position.

The coaxial connector 112 is secured to the coaxial receptacle 48 of the current diverting device 34 with the electrically conductive outer body of the coaxial connector 112 electrically coupled to the outer electrically conductive sleeve 50 of the coaxial receptacle 48. The central electrical conductor of the coaxial connector 112 extends into the central bore 50 of the coaxial receptacle 48 and engages the electrically conductive contact 54 extending into the bore 50. The central electrical conductor of the coaxial connector 112 exerts downward pressure on the electrically conductive contact 54 causing the contact 54 to disengage from the other electrically conductive contact 54. The current signal is diverted from the current carrying conductor 14 through the current sensing circuit 68 of the current probe 15 and back to the current carrying conductor 14 via one of the electrically conductive contacts 54 coupled to the central conductor of the coaxial connector 112 and to the current probe 15 via one of the electrically conductive leads 114 and 116 and the other electrically conductive contact 54 coupled to the outer electrically conductive sleeve 52 of the coaxial receptacle 48 and the electrically conductive outer body of the coaxial connector 112 and to the current probe 15 via the other of the electrically conductive leads 114 and 116. The mating of the coaxial connector 112 with the coaxial receptacle 48 of the current diverting device 34 couples the current probe 15 in series with the current carrying conductor 14 and is the second position of the current diverting device 34. Removal of the coaxial connector 112 from the current diverting device 34 releases the downward pressure on the electrically conducive contact 54 which causes the contacts 54 to re-engage each other. The above described current diverting device 34 and mating coaxial connector 112 are manufactured and sold by Amphenol, Corp., Wallingford, Conn., as a RF-Switch and RF-Probe under respective Part Nos. MCH-201 and MCH203.

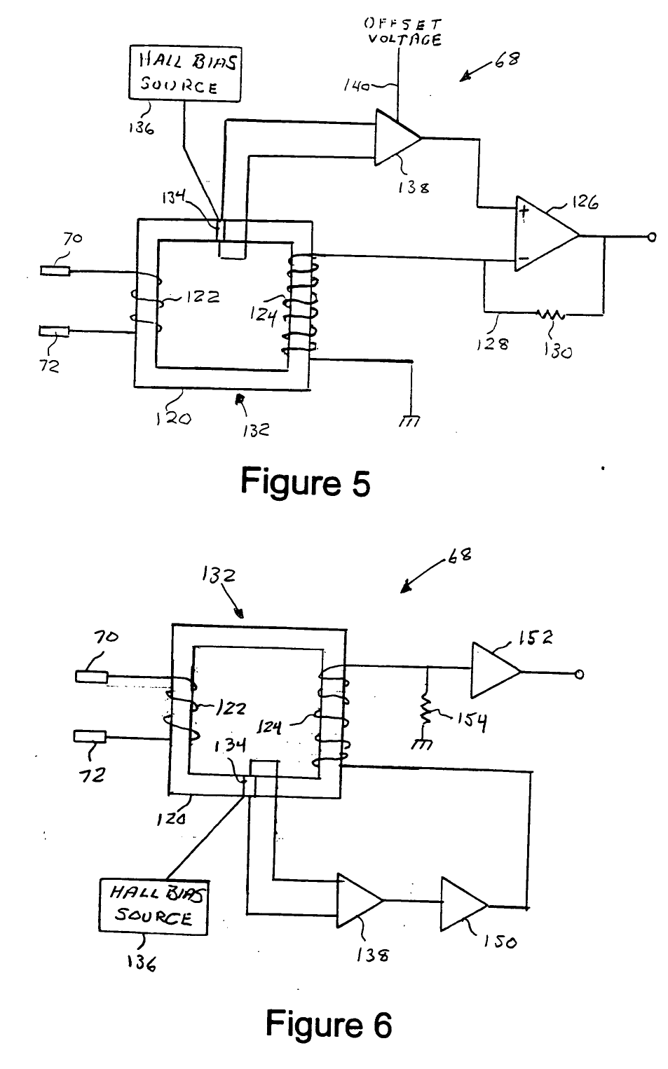

Referring to FIG. 5, there is shown a schematic representation of a current sensing circuit 68 usable in the current probe 15 of the current probing system 10. The current sensing circuit 68 has a ring-shaped core 120 of magnetic material defining an aperture. The current carrying conductor 14 is coupled via the first and second electrically conductive contacts 70 and 72 of the current probe 15 to a primary winding 122 that is coupled in series with the current carrying conductor 14. The current carrying conductor 14 is coupled in a flux linking relationship with ring-shaped magnetic core 120 via the primary winding 122. The current to be measured in the current carrying conductor 14 produces a magnetic flux in the magnetic core 122 and is linked to a secondary winding 124. One terminal of the secondary winding 124 is coupled to ground with the other terminal being coupled to the inverting input terminal of a transimpedance amplifier 126. The inverting input terminal of the transimpedance amplifier 126 is coupled to the output terminal of the amplifier 126 via a current signal path 128 having a transimpedance resistor 130. Thus the primary winding 122, the magnetic core 120 and the secondary winding 124 function as a transformer 132. A magneto-electric converter 134 is disposed within the magnetic core 120 substantially perpendicular to the lines of flux in the magnetic core 120. The magneto-electric converter 134 is preferably a thin film semiconductor Hall effect device having a first pair of terminals coupled to a bias source 136 and a second pair of terminals connected to differential inputs of amplifier 138. The amplifier 138 is preferably a high gain differential amplifier having low noise and high common mode rejection The single ended output of the differential amplifier 138 is coupled to the non-inverting input of the transimpedance amplifier 126. Offset control signals resulting from the degaussing of the current sensing circuit may also be applied to the differential amplifier 138 via an offset voltage line 140.

The current in the primary winding 122 produces a magnetic flux in the magnetic core 120 of the transformer 132 that is linked to the secondary winding 124 and the Hall effect device 134. DC or low frequency components of the current flowing the in the primary winding 122 generate a potential difference between the second pair of terminals of the Hall effect device 134. The voltage output of the Hall effect device 134 is coupled to the differential inputs of the amplifier 138. The output of amplifier 138 is coupled to the non-inverting input of the transimpedance amplifier 126. The changing signal level on the non-inverting input of the transimpedance amplifier 126 caused by the voltage generated by the Hall effect device 134 produces a corresponding change in the output voltage level of the transimpedance amplifier 126. The voltage at the output of the transimpedance amplifier 126 results in a current being generated in the current signal path 128 that is coupled to the secondary winding 124 of the transformer 132. The current flowing in the secondary winding 124 is opposite the current flowing in the primary winding 122 producing a magnetic flux in the magnetic core 120 that nulls the magnetic flux produced by the current flowing in the primary winding 122. This DC to low frequency feedback loop maintains an opposing current through the current signal path 128 that is equal to the DC or low current signal in the primary winding 122 of the transformer 132.

The high frequency components of the current flowing in the primary winding 122 results in a current being induced in the secondary winding 124 in a direction such as to produce a magnetic field in the magnetic core 120 that is opposite to the field created by the current in the primary winding 122. The current induced in the secondary winding 124 is coupled to the inverting input of the transimpedance amplifier 126. Since the inverting input is a virtual ground, the current in the secondary winding 124 is coupled via the current signal path 128 through the transimpedance resistor 130 to the output of the transimpedance amplifier 126 resulting in an amplified voltage output representative of the high frequency components of the current flowing in the primary winding 122. The transimpedance amplifier 126 functions as both a power amplifier for generating a bucking current for nulling the magnetic flux in the magnetic core 120 at DC to low current frequencies and as a transimpedance amplifier for higher frequencies. The output of the transimpedance amplifier 126 is to the oscilloscope 12 via the conductive cable 20.

FIG. 6 is a schematic representation of another current sensing circuit 68. Like elements from the previously are labeled the same in FIG. 6. The current sensing circuit 68 has a ring-shaped core 120 of magnetic material defining an aperture. The current carrying conductor 14 is coupled via the first and second electrically conductive contacts 70 and 72 of the current probe 15 to a primary winding 122 that is coupled in series with the current carrying conductor 14. The current carrying conductor 14 is coupled in a flux linking relationship with ring-shaped magnetic core 120 via the primary winding 122. The current to be measured in the current carrying conductor 14 produces a magnetic flux in the magnetic core 122 and is linked to a secondary winding 124. Thus the primary winding 122, the magnetic core 120 and the secondary winding 124 function as a transformer 132. A magneto-electric converter 134 is disposed within the magnetic core 120 substantially perpendicular to the lines of flux in the magnetic core 120. The magneto-electric converter 134 is preferably a thin film semiconductor Hall effect device having a first pair of terminals coupled between a bias source 136 and ground and a second pair of terminals connected to differential inputs of amplifier 138. The amplifier 138 is preferably a high gain differential amplifier having low noise and high common mode rejection The single ended output of the differential amplifier 138 is coupled to a power amplifier 150 whose output is coupled to one end of the secondary winding 124. The other end of the secondary winding 124 is coupled to the input of a voltage gain amplifier 152 via a transformer termination resistor 154 summing node.

The current in the primary winding 122 produces a magnetic flux in the magnetic core 120 of the transformer 132 that is linked to the secondary winding 124 and the Hall effect device 134. DC or low frequency components of the current flowing the in the primary winding 122 generate a potential difference between the second pair of terminals of the Hall effect device 134. The voltage output of the Hall effect device 134 is coupled to the differential amplifier 138 whose output is coupled to the power amplifier 150. The power amplifier 150 generates a current output that is coupled to the secondary winding 124. The current flowing in the secondary winding 124 from the power amplifier 150 is opposite the current flowing in the primary winding 122 producing a magnetic flux in the magnetic core 120 that nulls the magnetic flux produced by the current flowing in the primary winding 122. This opposing current through secondary winding representing the DC or low current signal in the primary winding 122 of the transformer 132 and is coupled to the input of the voltage gain amplifier 152 via the transformer termination resistor 154 summing node.

The high frequency components of the current flowing in the primary winding 122 results in a current being induced in the secondary winding 124 in a direction such as to produce a magnetic field in the magnetic core 120 that is opposite to the field created by the current in the primary winding 122. The current induced in the secondary winding 124 is coupled to the input of voltage gain amplifier 152 via transformer termination resistor 154 summing node. The current flowing in the secondary winding 124 from the power amplifier 150 nulls the magnetic flux in the magnetic core 120 for DC to low frequency current signals. The current induced in the secondary winding 124 by the current flowing in the primary winding 122 nulls the magnetic flux in the magnetic core 120 for high frequency current signals. The transition range between the current flowing in the secondary winding 124 from the power amplifier 150 and the current induced into the secondary winding 124 at higher frequencies results in the currents from both sources being summed at the transformer termination resistor 154 summing node. The voltage output of the voltage gain amplifier 152 is coupled to the oscilloscope 12 via the conductive cable 20.

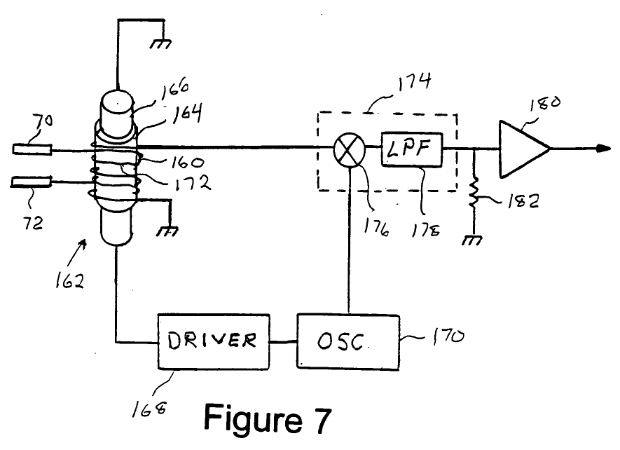

FIG. 7 is a schematic drawing of a further current sensing circuit 68. The current carrying conductor 14 is coupled via the first and second electrically conductive contacts 70 and 72 of the current probe 15 to an input winding 160 of a flux gate 162 that is coupled in series with the current carrying conductor 14. The flux gate 162 has a cylindrical magnetic core 164 around which the input winding 160 is wrapped. A conductive bar 166 is disposed coaxially through the cylindrical magnetic core 164 and is coupled to a driver circuit 168 coupled to an oscillator 170. A detecting coil 172 is placed around the cylindrical magnetic core 164 for detecting the magnetic flux of the current signal on the input winding and the magnetic flux of a signal from the oscillator 170. The detecting coil 172 is coupled to a detection circuit 174 having a mixer 176 that receives a signal from the oscillator 170 that is twice the frequency of the signal applied to the conductive bar 166. The mixer 176 is coupled to a low pass filter (LPF) 178 which in turn is coupled to an output amplifier 180 via a termination resistor 182.

The driver circuit 168 generates an oscillating drive current that causes the magnetic core 164 to saturate at the peaks of the drive current signal so that the magnetic flux leaves the magnetic core 164 and is aligned with the conductive bar 166. During these periods, the degree of magnetization of the core 164 in the longitudinal direction is decreasing. As the driving current approaches the zero crossing points, the magnetic flux again passes through the magnetic core 164. During these periods, the degree of magnetization of the core 164 in the longitudinal direction is increasing. The direction and density of the magnetic flux in the magnetic core changes according to the changes in the driving current. The voltage output induced into the detecting coil 172 with the current drive signal applied to the flux gate 162 has two cycles for each cycle of the drive current. A current signal applied to the input winding 160 modulates the magnetic flux in the magnetic core producing a modulated voltage output at detecting coil 172 representative of the current signal on the input winding. The modulated output voltage on the detecting coil 172 is coupled to the mixer 176. The mixer 176 multiplies the modulated output voltage with the oscillator signal that is twice the frequency of the drive current. The low pass filter 178 filters the output of the mixer to provide a voltage proportional to the current flowing the input winding 160. The output amplifier 180 receive the filter signal and generates an amplified voltage output. The above described current sensing circuits 68 are by example only and modifications to the above circuits may be made without departing from the scope of the invention.

A current probing system has been described having a current probe and a current diverting device. The current probe has a probe body and first and second electrically conductive contacts extending from one end of the probe body for connecting to the current diverting element. A current sensing circuit is coupled to the first and second electrically conductive contacts for generating an output signal representative of the current flowing in the current carrying conductor. An electrically conductive cable is coupled to receive the output signal from the current sensing device and extends from the other end of the probe body for coupling to an oscilloscope. The current diverting element is mountable on a current carrying conductor for serially coupling the current signal to a current probe.

It will be obvious to those having skill in the art that many changes may be made to the details of the above-described embodiments of this invention without departing from the underlying principles thereof. The scope of the present invention should, therefore, be determined only by the following claims.

What is claimed is:

1. A current probing system for use with an oscilloscope for acquiring a current signal from a current carrying conductor comprising:
a current diverting device mounted on the current carrying conductor passing the current signal on the current carrying conductor in a first position;
a current probe having a probe body and first and second electrically conductive contacts disposed in one end of the probe body with the first and second electrically conductive contacts being adapted for coupling to the current diverting device so that the current diverting device diverts the current signal from the current carrying conductor to the first and second electrically conductive contacts in a second position;
a current sensing circuit disposed in the probe body coupled to the first and second electrically conductive contacts for generating an output signal representative of the current flowing in the current carrying conductor; and
an electrically conductive cable coupled to receive the output signal from the current sensing device.

2. The current probing system as recited in claim 1 first and second electrically conductive contacts are first and second electrically conductive leads with each lead having one end coupled to a plug adapted for engaging electrically conductive contacts acting as switch elements in the current diverting device wherein downward pressure of the plug on at least one of the electrically conductive contacts of the current diverting device causes the electrically conductive contacts of the current diverting device to disengage in the second current diverting device position.

3. The current probing system as recited in claim 1 wherein the first and second electrically conductive contacts are pins extending from the end of the probe body for engaging electrically conductive contacts acting as switch elements in the current diverting device wherein downward pressure of the first and second electrically conductive contacts extending from the probe body on the electrically conductive contacts of the current diverting device causes the electrically conductive contacts of the current diverting device to disengage in the second current diverting device position.

4. The current probing system as recited in claim 3 wherein current diverting device further comprises a housing having a recess formed therein for receiving the electrically conductive contacts of the current diverting device with the electrically conductive contacts extending outside the housing for engaging the current carrying conductor, and one of the electrically conductive contacts extending across the recess in the housing for engaging the other electrically conductive contact with a portion of the electrically conductive contact extending across the recess in the housing resting on a pedestal extending upward in the housing recess.

5. The current probing system as recited in claim 1 further comprising a non-conductive protrusion extending from the probe body adjacent to the first and second electrically conductive contacts with the first and second electrically conductive contacts adapted for engaging electrically conductive contacts acting as switch elements in the current diverting device and the non-conductive protrusion adapted for engaging at least one of the electrically conductive contacts in the current diverting device wherein downward pressure of the non-conductive protrusion extending from the probe body on the electrically conductive contact of the current diverting device causes the electrically conductive contacts of the current diverting device to disengage in the second current diverting device position.

6. The current probing system as recited in claim 5 wherein the current diverting device further comprises a housing having electrically conductive contacts extending outside the housing for engaging the current carrying conductor with the electrically conductive contacts exposed in apertures formed in a top surface of the housing and separated by a central aperture, one of the electrically conductive contacts extending across the central aperture for engaging the other electrically conductive contact.

7. The current probing system as recited in claim 1 wherein the first and second electrically conductive contacts of the current probe form a pin having insulating material disposed in the pin for electrically isolating the first electrically conductive contact from the second electrically conductive contact, the pin extending from the end of the probe body for engaging electrically conductive contacts in the current diverting device wherein downward pressure of the electrically conductive pin on the electrically conductive contacts of the current diverting device causes the electrically conductive contacts of the current diverting device to disengage in the second current diverting device position.

8. The current probing system as recited in claim 7 wherein the current diverting device further comprises a housing having a recess formed therein for receiving the electrically conductive contacts of the current diverting device with the electrically conductive contacts extending outside the housing for engaging the current carrying conductor, the electrically conductive contacts disposed within the recess having a convex shape with the apexes of the convex shaped electrically conductive contacts engaging each other.

9. The current probing system as recited in claim 1 wherein the current sensing circuit further comprises a magnetic sensor coupled to the first and second electrically conductive contacts for sensing the magnetic flux of the current signal and coupled to amplifier circuitry for generating the output signal representative of the current flowing in the current carrying conductor.

10. The current probing system as recited in claim 9 wherein the magnetic sensor further comprises a transformer having primary and secondary windings and a magnetic core with the primary winding coupled the first and second electrically conductive contacts for receiving the current signal from the current carry conductor and inducing a magnetic flux within the magnetic core and the secondary winding for generating a current signal output in the secondary winding that is coupled to amplifier circuitry.

11. The current probing system as recited in claim 10 wherein the magnetic core of the transformer is ring-shaped and defines an aperture with primary winding disposed around a portion of the ring-shaped magnetic core of the transformer.

12. The current probing system as recited in claim 10 wherein the transformer further comprises a magneto-electric converter disposed in the magnetic core of the transformer and interacting with the magnetic flux within the magnetic core for generating a voltage signal representative of DC to low frequency current signals on the current carrying conductor with the voltage signal being coupled to the amplifier circuitry.

13. The current probing system as recited in claim 9 wherein the magnetic sensor further comprises a flux gate.
